(19) United States
(12) Patent Application Publication
(10) Pub. No.: US 2013/0069503 A1
(43) Pub. Date: Mar. 21, 2013

(54) RETENTION DEVICE FOR DATA STORAGE MODULE

(71) Applicants: XIU-QUAN HU, Shenzhen City (CN); LIN-HAN WU, Shenzhen City (CN); LI HOU, Shenzhen City (CN); WEI WANG, Shenzhen City (CN)

(72) Inventors: XIU-QUAN HU, Shenzhen City (CN); LIN-HAN WU, Shenzhen City (CN); LI HOU, Shenzhen City (CN); WEI WANG, Shenzhen City (CN)

(73) Assignees: HON HAI PRECISION INDUSTRY CO., LTD., Tu-Cheng (TW); HONG FU JIN PRECISION INDUSTRY (SHENZHEN) CO., LTD., Shenzhen City (CN)

(21) Appl. No.: 13/337,201

(22) Filed: Dec. 26, 2011

(30) Foreign Application Priority Data
Sep. 15, 2011 (CN) 201110273423.7

(51) Int. Cl. H05K 5/03

(52) U.S. Cl. 312/223.2

(57) ABSTRACT

A retention device for a data storage module of an electronic apparatus is disclosed. The retention device comprises a holder comprising a base, a top plate opposite to the base, and a plurality of side plates interconnecting the base and the cover; the base, the plurality of side plates and the cover cooperatively defining a chamber with an opening at a lateral side of the holder; a side cover comprising a first end pivotably connected one of the plurality of side plates, and a second end opposite to the first end, the first end being capable of rotating relative to the one of the plurality of side plates to seal or open the opening; and a fastener, wherein the second end of the side cover is fixed onto the holder by the fastener.

### BACKGROUND

1. Technical Field

The present disclosure relates to retention devices and, more particularly, to a retention device for a data storage module of an electronic apparatus.

2. Description of Related Art

Electronic apparatus, such as a desktop computer, tower computer, or server, usually includes storage modules, such as hard disk drives, compact disk read-only memory (CD-ROM) drives, and digital video disc (DVD) drives. These devices can be added to increase the functionality of the electronic apparatus as desired by a user.

Generally, a retention device is used to install a hard disk drive in a computer. However, the hard disk drive is usually fixed to the retention device via several screws. The fixing and assembling of the storage modules to the retention device may be time-consuming and inconvenient.

Therefore, what is needed is a retention device, which can overcome the above described shortcomings.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled view of a retention device, in accordance with an embodiment of the present disclosure.

FIG. 2 is a disassembled view of the retention device of FIG. 1.

FIG. 3 is a disassembled view showing a state of the retention device for mounting a storage module therein.

FIG. 4 is an assembled view of FIG. 3 showing the storage module being received in the retention device.

### DETAILED DESCRIPTION

Reference will now be made to the drawings to describe the present retention device, in detail.

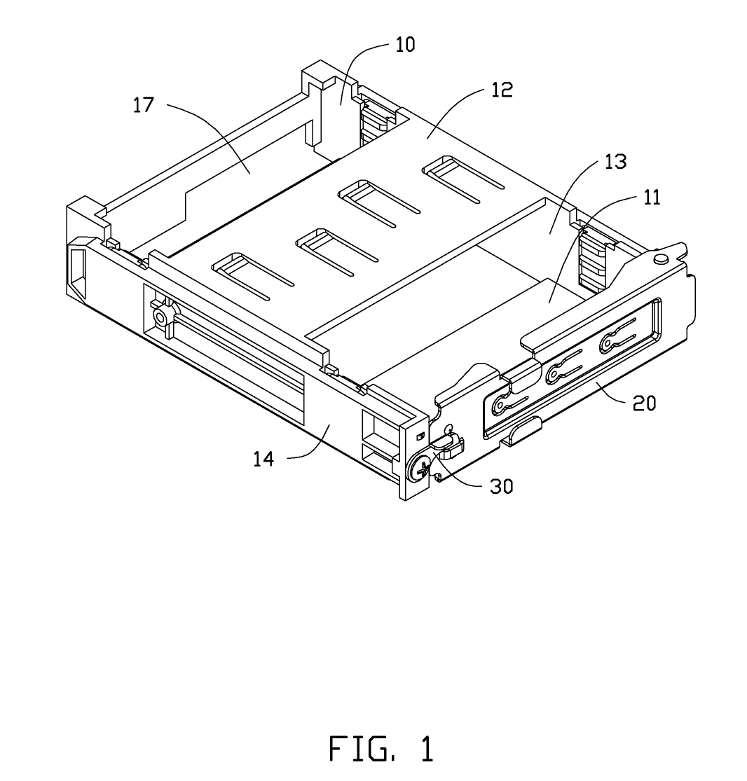

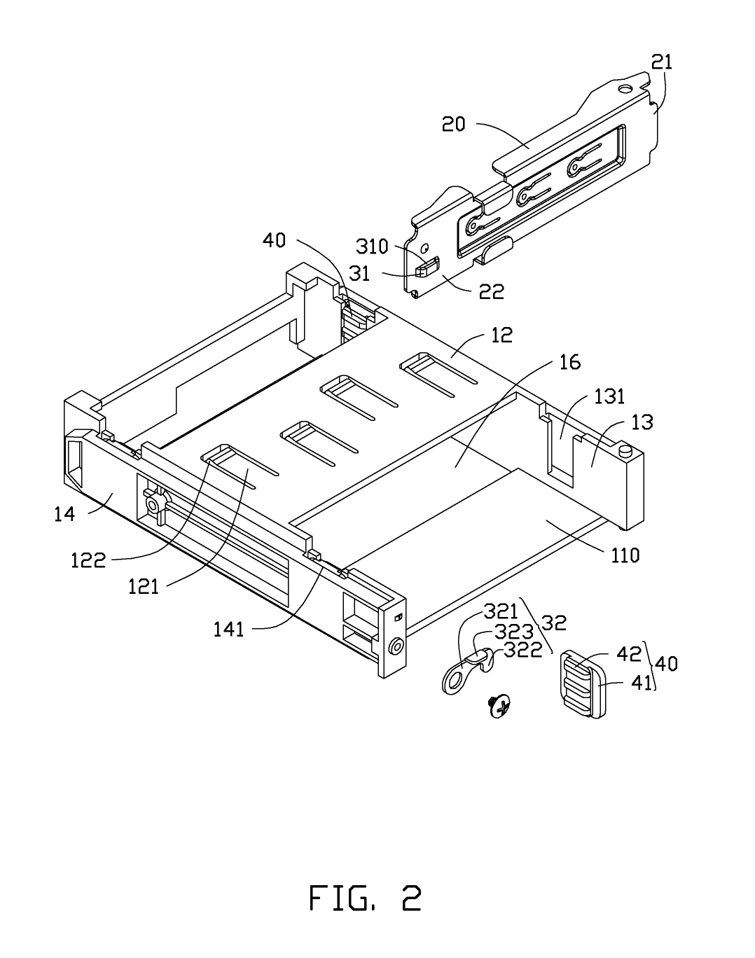

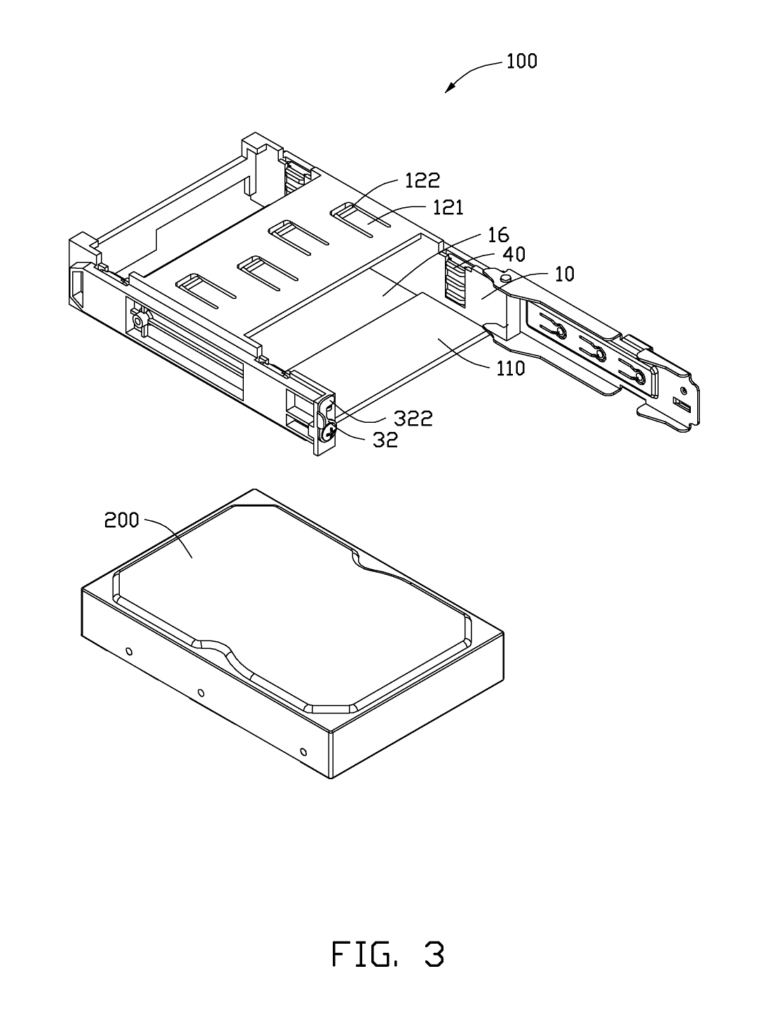

Referring to FIGS. 1 and 2, an exemplary embodiment of a retention device 100 comprises a holder 10, a side cover 20 and a fastener 30. The retention device 100 is used for receiving a storage module 200 (shown as FIG. 3) therein.

The holder 10 comprises a base 11, a top plate 12 opposite to the base 11, a first side plate 13, and a second side plate 14 extending from two opposite sides of the base 11 and interconnecting the base 11 and the top plate 12. The base 11, the first side plate 13, the second side plate 14, and the top plate 12 cooperatively define a rectangular chamber 16 with an opening 110 at a front end of the holder 10. In the present embodiment, each of the base 11 and the top plate 12 defines grooves 17 therein for dissipating heat generated from the storage module.

The side cover 20 is rectangular and engages in the opening 110 of the holder 10. The side cover 20 comprises a first end portion 21 pivotably connected to first side plate 13 of the holder 10 and a second end portion 22 opposite to the first end portion 21.

The fastener 30 locks the side cover 20 on the holder 10. The fastener 30 comprises a locking ring 31 and a latch 32. The locking ring 31 is U-shaped, and is fixed on the second portion 22 of the side cover 20. The locking ring 31 and the side cover 20 cooperatively define a cavity 310. In the present embodiment, the locking ring 31 is integrally formed with the side cover 20. The latch 32 comprises a main body 321, a catch 322 extending from one end of the main body 321, and an operating portion 323. The main body 321 is pivotably connected to the second side plate 14 of the holder. In this embodiment, the main body 321 defines a through hole therein, the second side plate 14 defines a mounting hole corresponding to the through hole of the main body. The through hole can be larger than the mounting hole. A screw matched with the mounting hole extends through the through hole of the main body 321 and engages into the mounting hole of the second side plate 14 to assemble the main body 321 on the second side plate 14. Since the through hole of the main body 321 is larger than the screw, the main body 321 is rotatable relative to the screw and the second side plate 14 after assembled on the second side plate 14.

The catch 322 is perpendicular to the main body 321. The operating portion 323 extends outwardly from a lateral side of the main body 321, and perpendicular to the main body 321 and the catch 322. The catch 322 is inserted into the cavity 310; therefore, the side cover 20 covers the opening 110 of the holder 10.

In the present embodiment, the top plate 12 of the holder 10 defines a plurality of elastic members 121. A first end of each of the plurality of elastic members 121 adjacent to the opening 110 of the holder 10, and is connected to the top plate 12. A second end of each of the plurality of elastic members defines an elastic portion 122 extending downwards from a free end of the first end. The storage module 200 is fixed on the holder 10 by an elastic force of each of the plurality of elastic members 121.

In the present embodiment, the retention device 100 further comprises a plurality of gaskets 40. Each of the plurality of gaskets 40 comprises a seat 41 and a plurality of ribs 42 extending from a front surface of the seat 41. In the present embodiment, the first side plate 13 defines a plurality of first grooves 131, and the second side plate 14 defines a plurality of second grooves 141. The seats 41 are respectively fixed in the pluralities of first and second grooves 131, 141, and the plurality of ribs 42 face to the chamber 16. Therefore, the storage module 200 is received in the chamber 16 with the plurality of ribs 42 abutting side surfaces of the storage module 200 to protect the storage module 200.

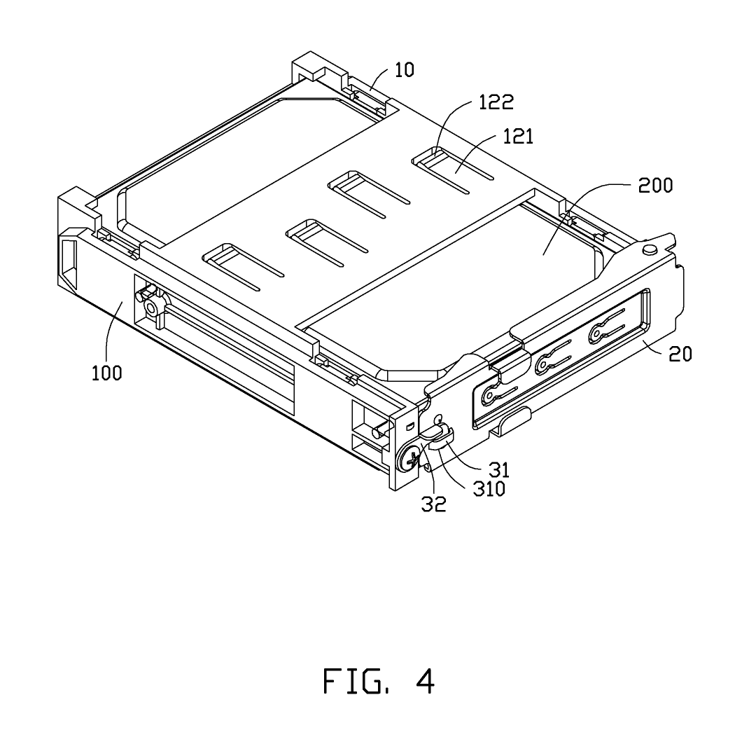

Referring to FIG. 3 in assembly, the side cover 20 is rotates out from the opening 110, and the storage module 200 is thus inserted into chamber 16 of the holder 10 through the opening 110. The plurality of ribs 42 of the plurality of gaskets 40 abut against side surfaces of the storage module 200, and the elastic portion 122 of each of the plurality of elastic members 121 abuts against a top surface of the storage module 200. Referring to FIG. 4, after the storage module 200 is in the chamber 16, the side cover 20 is rotates back to seal the opening 110 of the holder 10, and latch 32 is rotates towards the side cover 20 to make the catch 322 of the latch 32 engage in the cavity 310 of the locking ring 31; therefore, the storage module 200 is fixed in the holder 10.

If the storage module 200 needs to be replaced, the latch 32 can be easily rotated by operating the operating portion 323 to make the catch 322 disengage from the cavity 310, thus the side cover 20 can be pull out to draw the storage module 200 from the chamber 16 out. Thus, the storage module 200 can be easily assembled to and disassembled from retention device 100, without using of a tool.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A retention device comprising:
a holder comprising a base, a top plate opposite to the base, and a plurality of side plates interconnecting the base and the cover; the base, the plurality of side plates and the cover cooperatively defining a chamber with an opening at a lateral side of the holder;
a side cover comprising a first end pivotably connected one of the plurality of side plates, and a second end opposite to the first end, the first end being capable of rotating relative to the one of the plurality of side plates to seal or open the opening; and
a fastener, wherein the second end of the side cover is fixed onto the holder by the fastener.

2. The retention device of claim 1, wherein the fastener comprises a locking ring and a latch, the locking ring and the side cover cooperatively define a cavity, the latch is configure to be inserted into the cavity.

3. The retention device of claim 2, wherein the plurality of side plates comprises a first side plate and a second side plate, the side cover being pivotably connected with the first side plate, the latch being pivotally connected with the second side plate.

4. The retention device of claim 3, wherein the latch comprises a main body pivotably connected with the second side plate and a catch extending from the main body, the catch is configured to be inserted into the cavity.

5. The retention device of claim 2, wherein the locking ring is integrally formed with the side cover.

6. The retention device of claim 1, wherein the top plate of the holder defines a plurality of elastic members, each of the plurality of elastic members comprising an elastic portion extending downwardly from a free end of each of the plurality of elastic members.

7. The retention device of claim 1, further comprising a plurality of gaskets arranged at each of the plurality of side plates of the holder.

8. The retention device of claim 7, wherein each of the plurality of gaskets comprises a seat and a plurality of ribs extending inwardly from the seat.

9. A retention device for supporting a storage device, the retention device comprising:
a holder defining a chamber therein for receiving the storage device and an opening at a lateral side of the holder communicating the chamber;
a side cover comprising a first end rotatably connected to the holder at the lateral side, the side cover is configured to cover the opening; and
a fastener comprising a cavity and a latch engaged in the cavity, the latch being formed on either the side cover or the holder, and the cavity being defined in another one of the side cover or the holder.

10. The retention device of claim 9, wherein the holder comprises a base, a top plate opposite to the base, and a plurality of side plates extending from the base and interconnecting the base and the cover; the base, the plurality of side plates and the cover cooperatively defining the chamber with the opening at the lateral side of the holder.

11. The retention device of claim 10, wherein the latch is rotatable fixed on either the side cover or the holder.

12. The retention device of claim 11, wherein the plurality of side plates comprises a first side plate and a second side plate, the side cover being pivotably connected with the first side plate, the latch being pivotally connected with the second side plate.

13. The retention device of claim 12, wherein the latch comprises a main body pivotably connected with the second side plate and a catch extending from the main body, the catch is configured to be inserted into the cavity.
